(19) United States
(12) Patent Application Publication
(10) Pub. No.: US 2025/0149296 A1
(43) Pub. Date: May 8, 2025

(54) PLASMA PROCESSING APPARATUS AND PLASMA PROCESSING METHOD

(71) Applicant: Tokyo Electron Limited, Tokyo (JP)

(72) Inventor: Chishio KOSHIMIZU, Miyagi (JP)

(73) Assignee: Tokyo Electron Limited, Tokyo (JP)

(21) Appl. No.: 19/001,893

(22) Filed: Dec. 26, 2024

Related U.S. Application Data
(63) Continuation of application No. PCT/JP2023/022815, filed on Jun. 20, 2023.

(30) Foreign Application Priority Data
Jun. 29, 2022 (JP) 2022-104274

(51) Int. Cl. H01J 37/32

(52) U.S. Cl. CPC H01J 37/32165; H01J 37/32449

(57) ABSTRACT

A plasma processing apparatus includes a chamber, a substrate support, a gas supplier for supplying gas into the chamber, a radio-frequency power supply for supplying a source radio-frequency power to generate plasma, and a bias power supply for generating electric bias. During a first processing period, the radio-frequency power supply uses frequencies, which are included in a first frequency set determined to reduce a degree of reflection of the source radio-frequency power from a load, as source frequencies of the source radio-frequency power for each of phase periods in a waveform period of the electric bias. During a second processing period, the radio-frequency power supply uses frequencies, which are included in a second frequency set different from the first frequency set and determined to reduce the degree of reflection, as the source frequencies for each of the phase periods.

### CROSS-REFERENCE TO RELATED APPLICATIONS

This application is a bypass continuation application of international application No. PCT/JP2023/022815 having an international filing date of Jun. 20, 2023 and designating the United States, the international application being based upon and claiming the benefit of priority from Japanese Patent Application No. 2022-104274, filed on Jun. 29, 2022, the entire contents of each are incorporated herein by reference.

### TECHNICAL FIELD

The present disclosure relates to a plasma processing apparatus and a plasma processing method.

### BACKGROUND

A plasma processing apparatus is used in plasma processing of a substrate. The plasma processing apparatus uses a bias radio-frequency power to draw ions from plasma generated inside a chamber into the substrate. Patent Document 1 discloses a plasma processing apparatus which modulates a power level and frequency of a bias radio-frequency power.

### PRIOR ART DOCUMENT

### Patent Document

Patent Document 1: Japanese Laid-Open Patent Publication No. 2009-246091

### SUMMARY

According to one embodiment of the present disclosure, a plasma processing apparatus includes a chamber, a substrate support arranged inside the chamber, a gas supplier configured to supply a gas into the chamber, a radio-frequency power supply configured to a supply source radio-frequency power to generate plasma from the gas inside the chamber, and a bias power supply electrically coupled to the substrate support and configured to generate electric bias, wherein during a first processing period in which a first processing condition including supplying a first processing gas from the gas supplier into the chamber is applied, the radio-frequency power supply uses a plurality of frequencies, which are included in a first frequency set determined to reduce a degree of reflection of the source radio-frequency power from a load, as source frequencies of the source radio-frequency power for each of a plurality of phase periods in a waveform period of the electric bias, and during a second processing period in which a second processing condition including supplying a second processing gas from the gas supplier into the chamber is applied, the radio-frequency power supply uses a plurality of frequencies, which are included in a second frequency set different from the first frequency set and determined to reduce the degree of reflection of the source radio-frequency power from the load, as the source frequencies for each of the plurality of phase periods in the waveform period of the electric bias.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a diagram for explaining a configuration example of a plasma processing system.

FIG. 2 is a diagram for explaining a configuration example of a capacitively coupled plasma processing apparatus.

FIG. 3 is a diagram showing a configuration example of a power supply system in a plasma processing apparatus according to one exemplary embodiment.

FIG. 4 is a timing chart showing an example of electric bias used in the plasma processing apparatus according to one exemplary embodiment.

FIG. 5 is a timing chart showing an example of electric bias and a source frequency of source radio-frequency power used in the plasma processing apparatus according to one exemplary embodiment.

FIG. 6 is a timing chart relating to the plasma processing apparatus according to one exemplary embodiment.

FIGS. 7A to 7C show a pulse period in a pulse period sequence relating to the plasma processing apparatus according to one exemplary embodiment.

FIG. 8 is a flowchart of a plasma processing method according to one exemplary embodiment.

### DETAILED DESCRIPTION

Various exemplary embodiments will now be described in detail with reference to the drawings. Throughout the drawings, the same or corresponding parts are designated by the same reference numerals. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

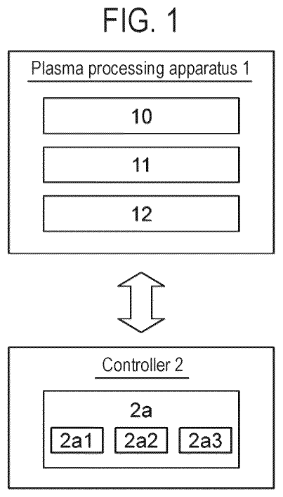

FIG. 1 is a diagram for explaining a configuration example of a plasma processing system. In one embodiment, the plasma processing system includes a plasma processing apparatus 1 and a controller 2. The plasma processing system is an example of a substrate processing system, and the plasma processing apparatus 1 is an example of a substrate processing apparatus. The plasma processing apparatus 1 includes a plasma processing chamber 10, a substrate support 11, and a plasma generator 12. The plasma processing chamber 10 has a plasma processing space. Further, the plasma processing chamber 10 includes at least one gas supply port for supplying at least one processing gas to the plasma processing space therethrough, and at least one gas exhaust port for exhausting a gas from the plasma processing space therethrough. The gas supply port is connected to a gas supplier 20 described later. The gas exhaust port is connected to an exhaust system 40 described later. The substrate support 11 is arranged inside the plasma processing space, and has a substrate support surface for supporting a substrate thereon.

The plasma generator 12 is configured to generate plasma from at least one processing gas supplied into the plasma processing space. The plasma formed in the plasma processing space may be capacitively coupled plasma (CCP), inductively coupled plasma (ICP), electron-cyclotron-resonance plasma (ECR plasma), helicon wave plasma (HWP), or surface wave plasma (SWP).

The controller 2 processes computer-executable instructions that cause the plasma processing apparatus 1 to execute various processes described in the present disclosure. The controller 2 may be configured to control individual elements of the plasma processing apparatus 1 to execute various processes described herein. In one embodiment, a part or the entirety of the controller 2 may be included in the plasma processing apparatus 1. The controller 2 may include a processor 2a1, a memory 2a2, and a communication interface 2a3. The controller 2 is implemented by, for example, a computer 2a. The processor 2a1 may be configured to perform various control operations by reading a program from the memory 2a2 and executing the read program. This program may be stored in the memory 2a2 in advance, or may be acquired via a medium when necessary. The acquired program is stored in the memory 2a2 and is read from the memory 2a2 by the processor 2a1 and executed. The medium may be various storage media readable by the computer 2a, or may be a communication line connected to the communication interface 2a3. The processor 2a1 may be a CPU (Central Processing Unit). The memory 2a2 may include a RAM (Random Access Memory), a ROM (Read Only Memory), an HDD (Hard Disk Drive), an SSD (Solid State Drive), or a combination thereof. The communication interface 2a3 may communicate with the plasma processing apparatus 1 via a communication line such as a LAN (Local Area Network) or the like.

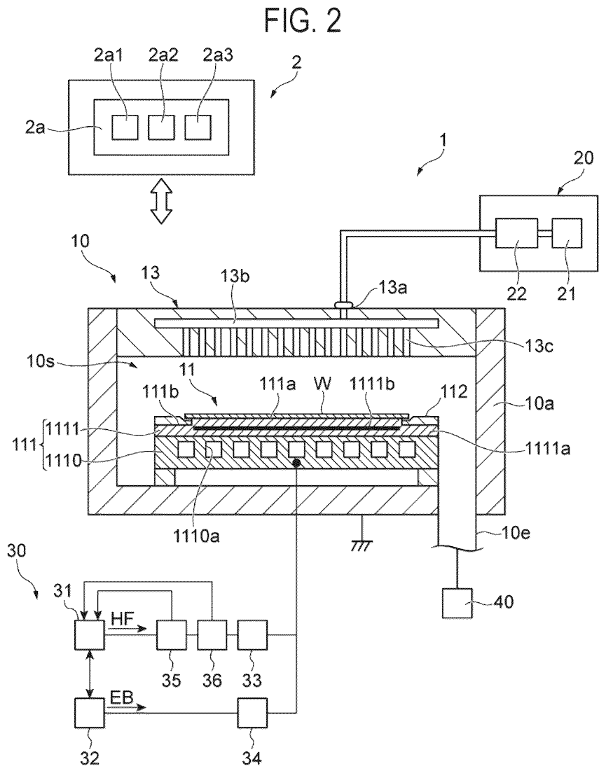

A configuration example of a capacitively coupled plasma processing apparatus will be described below as an example of the plasma processing apparatus 1. FIG. 2 is a diagram for explaining the configuration example of the capacitively coupled plasma processing apparatus.

The capacitively coupled plasma processing apparatus 1 includes a plasma processing chamber 10, a gas supplier 20, a power supply system 30, and an exhaust system 40. The plasma processing apparatus 1 further includes a substrate support 11 and a gas introducer. The gas introducer is configured to introduce at least one processing gas into the plasma processing chamber 10. The gas introducer includes a shower head 13. The substrate support 11 is arranged inside the plasma processing chamber 10. The shower head 13 is arranged above the substrate support 11. In one embodiment, the shower head 13 constitutes at least a part of the ceiling of the plasma processing chamber 10. The plasma processing chamber 10 has a plasma processing space 10s defined by the shower head 13, a sidewall 10a of the plasma processing chamber 10, and the substrate support 11. The plasma processing chamber 10 is grounded. The substrate support 11 is electrically insulated from a housing of the plasma processing chamber 10.

The substrate support 11 includes a main body 111 and a ring assembly 112. The main body 111 has a central region 111a for supporting a substrate W and an annular region 111b for supporting the ring assembly 112. A wafer is an example of the substrate W. The annular region 111b of the main body 111 surrounds the central region 111a of the main body 111 in a plan view. The substrate W is arranged on the central region 111a of the main body 111, and the ring assembly 112 is arranged on the annular region 111b of the main body 111 so as to surround the substrate W on the central region 111a of the main body 111. Therefore, the central region 111a is also called a substrate support surface for supporting the substrate W thereon, and the annular region 111b is also called a ring support surface for supporting the ring assembly 112 thereon.

In one embodiment, the main body 111 includes a base 1110 and an electrostatic chuck 1111. The base 1110 includes a conductive member. The electrostatic chuck 1111 is arranged on the base 1110. The electrostatic chuck 1111 includes a ceramic member 1111a and an electrostatic electrode 1111b arranged inside the ceramic member 1111a. The ceramic member 1111a has a central region 111a. In one embodiment, the ceramic member 1111a also has an annular region 111b. Another member surrounding the electrostatic chuck 1111, such as an annular electrostatic chuck or an annular insulating member, may have the annular region 111b. In this case, the ring assembly 112 may be arranged on the annular electrostatic chuck or the annular insulating member, or may be arranged on both the electrostatic chuck 1111 and the annular insulating member.

The ring assembly 112 includes one or more annular members. In one embodiment, the one or more annular members include one or more edge rings and at least one cover ring. The edge rings are made of a conductive or insulating material, and the cover ring is made of an insulating material.

Further, the substrate support 11 may include a temperature adjustment module configured to adjust a temperature of at least one of the electrostatic chuck 1111, the ring assembly 112, or the substrate to a target temperature. The temperature adjustment module may include a heater, a heat transfer medium, a flow path 1110a, or a combination thereof. A heat transfer fluid such as a brine or a gas flows through the flow path 1110a. In one embodiment, the flow path 1110a is formed in the base 1110, and one or more heaters are arranged inside the ceramic member 1111a of the electrostatic chuck 1111. Further, the substrate support 11 may include a heat-transfer gas supplier configured to supply a heat-transfer gas to a gap between a back surface of the substrate W and the central region 111a.

The shower head 13 is configured to introduce at least one processing gas from the gas supplier 20 into the plasma processing space 10s. The shower head 13 includes at least one gas supply port 13a, at least one gas diffusion chamber 13b, and a plurality of gas introduction holes 13c. The processing gas supplied to the gas supply port 13a passes through the gas diffusion chamber 13b and is introduced into the plasma processing space 10s via the gas introduction holes 13c. Further, the shower head 13 includes at least one upper electrode. In addition to the shower head 13, the gas introducer may include one or more side gas injectors (SGI) attached to one or more openings formed in the sidewall 10a.

The gas supplier 20 may include at least one gas source 21 and at least one flow rate controller 22. In one embodiment, the gas supplier 20 is configured to supply at least one processing gas from the corresponding gas source 21 via the corresponding flow rate controller 22 to the shower head 13. The flow rate controller 22 may include, for example, a mass flow controller or a pressure-controlled flow rate controller. Further, the gas supplier 20 may include at least one flow modulation device for modulating or pulsing a flow rate of the at least one processing gas.

The exhaust system 40 may be connected to, for example, the gas exhaust port 10e provided at the bottom of the plasma processing chamber 10. The exhaust system 40 may include a pressure regulation valve and a vacuum pump. An internal pressure of the plasma processing space 10s is adjusted by the pressure regulation valve. The vacuum pump may include a turbo-molecular pump, a dry pump, or a combination thereof.

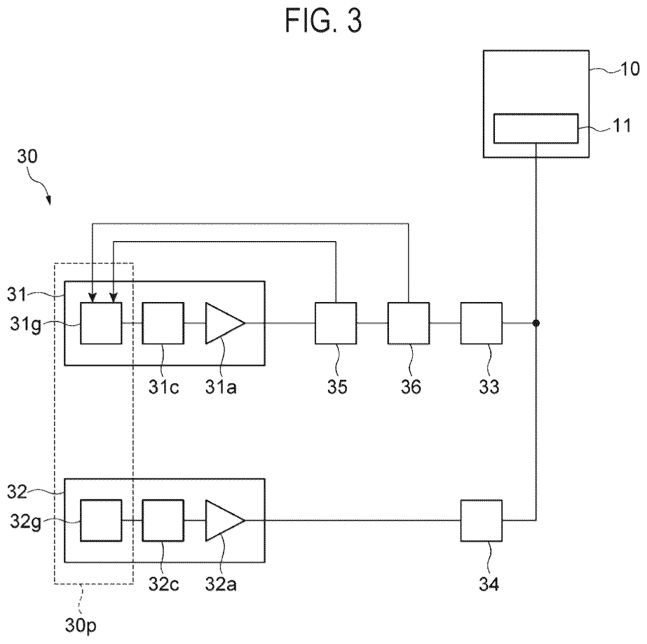

FIG. 3 will be referred to below together with FIG. 2. FIG. 3 is a diagram showing a configuration example of the power supply system in the plasma processing apparatus according to one exemplary embodiment. The power supply system 30 includes a radio-frequency power supply 31 and a bias power supply 32. The radio-frequency power supply 31 constitutes the plasma generator 12 according to one embodiment. The radio-frequency power supply 31 is configured to generate source radio-frequency power HF. The source radio-frequency power HF has a source frequency f_{HF}. The source frequency f_{HF} may be a frequency falling within a range of 10 MHz to 150 MHz. A power level of the source radio-frequency power HF or its pulse HFP, which will be described later, may be designated to the radio-frequency power supply 31 by the controller 2.

The radio-frequency power supply 31 is configured to supply the source radio-frequency power HF to the radio-frequency electrode. The radio-frequency electrode may be provided inside the substrate support 11. The radio-frequency electrode may be the conductive member or at least one electrode provided in the ceramic member 1111a of the base 1110. Alternatively, the radio-frequency electrode may be an upper electrode. When the source radio-frequency power HF is supplied to the radio-frequency electrode, plasma is generated from the gas inside the plasma processing chamber 10.

The radio-frequency power supply 31 is electrically connected to the radio-frequency electrode via a matching device 33. The matching device 33 has a variable impedance. The variable impedance of the matching device 33 is set so as to reduce the reflection of the source radio-frequency power HF of the radio-frequency power supply 31 from a load. The matching device 33 may be controlled by, for example, the controller 2.

In one embodiment, the radio-frequency power supply 31 may include a signal generator 31g, a D/A converter 31c, and an amplifier 31a. The signal generator 31g generates a radio-frequency signal having a source frequency f_{HF.} The signal generator 31g may include a programmable logic device such as a programmable processor or a field-programmable gate array (FPGA). The signal generator 31g may include a single programmable device together with the signal generator 32g described later, or may include a programmable device provided separately from the signal generator 32g.

An output of the signal generator 31g is connected to an input of the D/A converter 31c. The D/A converter 31c converts the radio-frequency signal from the signal generator 31g into an analog signal. An output of the D/A converter 31c is connected to an input of the amplifier 31a. The amplifier 31a amplifies the analog signal from the D/A converter 31c to generate the source radio-frequency power HF. An amplification factor of the amplifier 31a is designated to the radio-frequency power supply 31 by the controller 2. The radio-frequency power supply 31 may not include the D/A converter 31c. In this case, the output of the signal generator 31g is connected to the input of the amplifier 31a, and the amplifier 31a amplifies the radio-frequency signal from the signal generator 31g to generate the source radio-frequency power HF. Alternatively, the amplifier 31a may directly receive frequency information from the signal generator 31g and may generate the source radio-frequency power HF having a source frequency specified by the frequency information.

The bias power supply 32 is electrically coupled to the substrate support 11. The bias power supply 32 is electrically connected to a bias electrode in the substrate support 11 and configured to supply electric bias EB to the bias electrode. The bias electrode may be the conductive member of the base 1110 or at least one electrode provided in the ceramic member 1111a. The bias electrode may be common to the radio-frequency electrode. When the electric bias EB is supplied to the bias electrode, ions from the plasma are attracted to the substrate W.

In one embodiment, as shown in FIG. 3, the bias power supply 32 may include a signal generator 32g, a D/A converter 32c, and an amplifier 32a. The signal generator 32g generates a bias signal having a specified waveform. The signal generator 32g may be constituted with a programmable processor or a programmable logic device such as an FPGA.

An output of the signal generator 32g is connected to an input of the D/A converter 32c. The D/A converter 32c converts the bias signal from the signal generator 32g into an analog signal. An output of the D/A converter 32c is connected to an input of the amplifier 32a. The amplifier 32a amplifies the analog signal from the D/A converter 32c to generate the electric bias EB. An amplification factor of the amplifier 32a is designated to the bias power supply 32 by the controller 2. The bias power supply 32 may not include the D/A converter 32c. In this case, the output of the signal generator 32g is connected to the input of the amplifier 32a, and the amplifier 32a generates the electric bias EB from the voltage waveform or power information of the bias signal from the signal generator 32g.

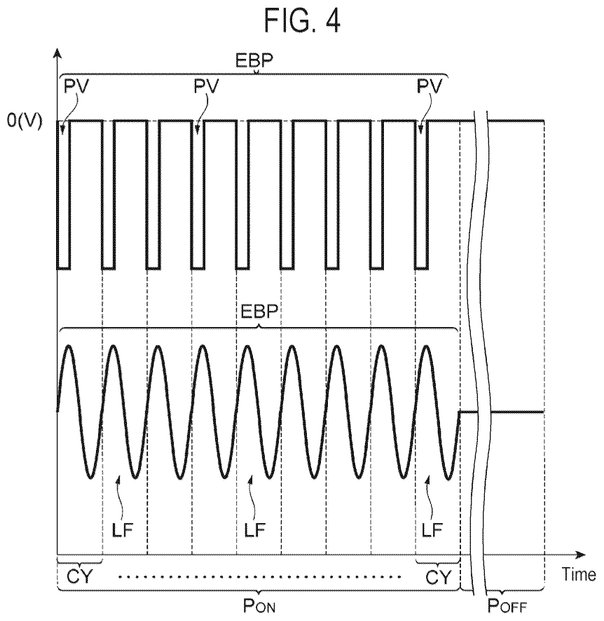

FIG. 4 will be referred to below together with FIGS. 2 and 3. FIG. 4 is a timing chart showing an example of the electric bias used in the plasma processing apparatus according to one exemplary embodiment. The electric bias EB or a pulse EBP thereof, which will be described later, has a waveform period CY as shown in FIG. 4, and is periodically supplied from the bias power supply 32 to the bias electrode. The waveform period CY of the electric bias EB is determined by a bias frequency. The bias frequency is, for example, a frequency of 100 kHz or more and 50 MHz or less. A time length of the waveform period CY of the electric bias EB is the reciprocal of the bias frequency.

The electric bias EB may be the bias radio-frequency power LF as shown in FIG. 4. That is, the electric bias EB may have a sinusoidal waveform whose frequency is the bias frequency. In this case, the bias power supply 32 is electrically connected to the bias electrode via a matching device 34. A variable impedance of the matching device 34 is set so as to reduce the reflection of the bias radio-frequency power LF from a load.

Alternatively, the electric bias EB may be a voltage pulse sequence. The voltage pulse sequence includes a periodically-generated voltage pulse PV. The voltage pulse PV is applied to the bias electrode within the waveform period CY. The voltage pulse PV is periodically applied to the bias electrode at a time interval equal to the time length of the waveform period CY. A waveform of the voltage pulse PV may be a square waveform, a triangular waveform, or any other waveform. A polarity of the voltage of the voltage pulse PV is set so as to generate a potential difference between the substrate W and the plasma to draw ions from the plasma into the substrate W. The voltage pulse PV may be a negative voltage pulse or a negative DC voltage pulse. When the electric bias EB includes a sequence of voltage pulses PV, the plasma processing apparatus 1 may not include the matching device 34.

The level of the electric bias EB or its pulse EBP may be designated to the bias power supply 32 by the controller 2. When the electric bias EB or its pulse EBP is the bias radio-frequency power LF, the level of the electric bias EB or its pulse EBP is a power level of the bias radio-frequency power LF. When the electric bias EB or its pulse is a voltage pulse sequence, the level of the electric bias EB or its pulse EBP is a magnitude of the voltage level of the voltage pulse PV in the negative direction with respect to a reference voltage level (e.g., 0 V). The level of the electric bias EB or its pulse EBP may be an absolute value of the negative voltage level of the voltage pulse PV.

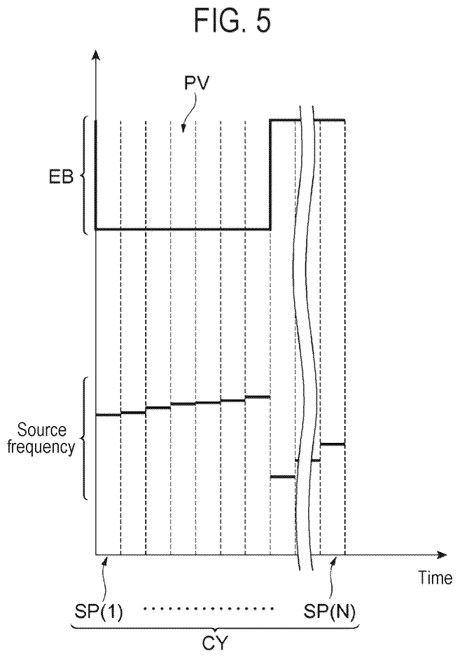

FIG. 5 is a timing chart showing an example of the source frequency of the electric bias and the source radio-frequency power used in the plasma processing apparatus according to one exemplary embodiment. As shown in FIG. 5, the radio-frequency power supply 31 changes the source frequency within a waveform period CY of the electric bias EB so as to reduce a degree of reflection of the source radio-frequency power HF from a load. In the plasma processing apparatus 1, the waveform period CY of the electric bias EB is divided into a plurality of phase periods SP. The radio-frequency power supply 31 changes the source frequency in the plurality of phase periods SP by using a plurality of source frequencies for each of the plurality of phase periods SP. The change of the source frequency within the waveform period CY of the electric bias EB will be described later.

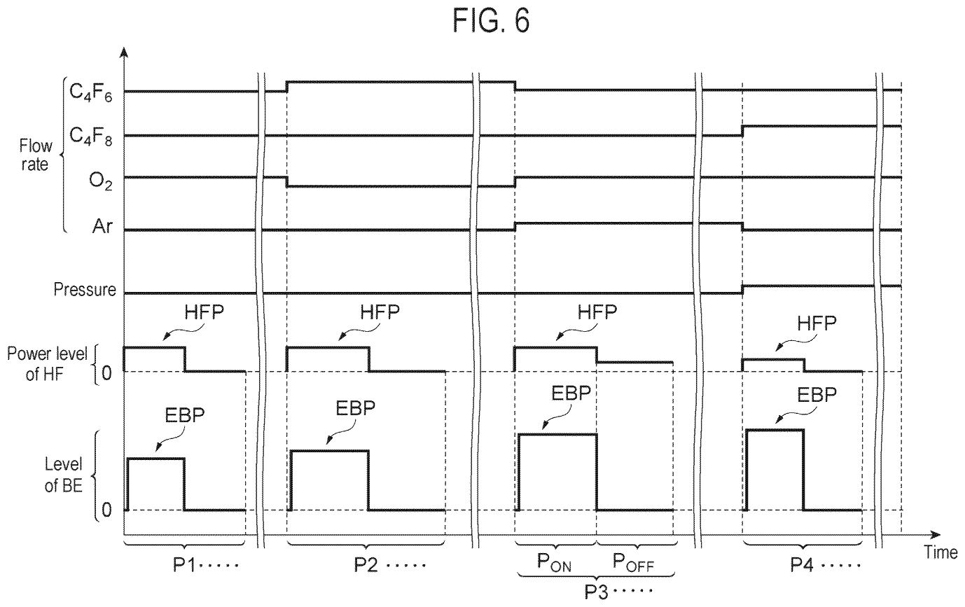

Hereinafter, FIG. 6 will be referred to together with FIG. 2 to FIG. 5. FIG. 6 is a timing chart relating to the plasma processing apparatus according to one exemplary embodiment. As shown in FIG. 6, the radio-frequency power supply 31 may be configured to generate a pulse HFP of the source radio-frequency power HF and supply the same to the radio-frequency electrode. The pulse HFP may be repeatedly supplied. The pulse HFP may be periodically supplied. A pulse period of the pulse HFP (e.g., any one of the processing periods P1 to P4 described later) and a duty ratio of the pulse HFP may be designated by the controller 2. The pulse period of the pulse HFP (e.g., each of the processing periods P1 to P4 described later) includes a period (ON period) in which the pulse HFP is in an ON (or high power level) state and a period (OFF period) in which the pulse HFP is in an OFF (or low power level) state. The duty ratio of the pulse HFP is a proportion of the period in which the pulse HFP is in the ON (or high power level) state in the pulse period of the pulse HFP.

As shown in FIGS. 4 and 6, the bias power supply 32 may be configured to generate a pulse EBP of the electric bias EB and supply the same to the bias electrode. The pulse EBP may be repeatedly supplied. The pulse EBP may be periodically supplied. A pulse period of the pulse EBP (e.g., any one of the processing periods P1 to P4 described later) and a duty ratio of the pulse EBP may be designated by the controller 2. The pulse period of the pulse EBP (e.g., each of the processing periods P1 to P4 described later) includes a period (ON period P_{ON}) in which the pulse EBP is set to ON and a period (OFF period P_{OFF}) in which the pulse EBP is set to OFF. The duty ratio of the pulse EBP is a proportion of the ON period PON in the pulse period of the pulse EBP.

In the plasma processing apparatus 1, a plurality of processing conditions different from each other are applied to the substrate W during a plurality of processing periods (e.g., the processing periods P1 to P4 in FIG. 6). Recipe data specifying the plurality of processing conditions and the plurality of processing periods may be stored in the memory 2a2 of the controller 2. The controller 2 controls individual parts of the plasma processing apparatus 1 according to the recipe data to perform plasma processing under a corresponding processing condition among the plurality of processing conditions during each of the plurality of processing periods.

Each of the plurality of processing conditions includes supplying a processing gas from the gas supplier 20 into the plasma processing chamber 10, the processing gas being different from a processing gas supplied from the gas supplier 20 into the plasma processing chamber 10 under each of the other processing conditions among the plurality of processing conditions. The plurality of processing periods includes at least a first processing period (e.g., the processing period P1 in FIG. 6) and a second processing period (e.g., the processing period P2 in FIG. 6). A processing gas (first processing gas) under the first processing condition applied to the substrate W in the first processing period is different from a processing gas (second processing gas) under the second processing condition applied to the substrate W in the second processing period.

Each of the plurality of processing gases for each of the plurality of processing conditions may contain at least one gas component that is different from all of the gas components in each of the other processing gases among the plurality of processing gases, or each of the plurality of processing gases for each of the plurality of processing conditions may contain the same plurality of gas components as each of the other processing gases. However, a flow rate of at least one of the plurality of gas components may be different from a flow rate of a corresponding gas component in the other processing gas.

In one example, as shown in FIG. 6, the plurality of processing periods includes the processing periods P1 to P4. The plurality of processing gases under the plurality of processing conditions for each of the processing periods P1 to P4 contain the same gas components as the gas components of each of the other processing gases among the plurality of processing gases. Specifically, each of the processing gases under the plurality of processing conditions for each of the processing periods P1 to P4 contains a C₄F₆ gas, a C₄F₈ gas, an O₂ gas, and an Ar gas. However, the flow rate of at least one of the gas components of the processing gas in each of the processing periods P1 to P4 is different from the flow rate of the corresponding gas components in the other processing periods among the processing periods P1 to P4.

Specifically, as shown in FIG. 6, the flow rate of the O₂ gas in the processing period P1 is greater than the flow rate of the O₂ gas in the processing period P2. The flow rate of the C₄F₆ gas in the processing period P2 is greater than the flow rate of the C₄F₆ gas in the processing period P1, and the flow rate of the O₂ gas in the processing period P2 is less than the flow rate of the O₂ gas in the processing period P1. The flow rate of the C₄F₆ gas in the processing period P3 is less than the flow rate of the C₄F₆ gas in the processing period P2, the flow rate of the O₂ gas in the processing period P3 is greater than the flow rate of the O₂ gas in the processing period P2, and the flow rate of the Ar gas in the processing period P3 is greater than the flow rate of the Ar gas in the processing period P2. The flow rate of the C₄F₈ gas in the processing period P4 is greater than the flow rate of the C₄F₈ gas in the processing period P3, and the flow rate of the Ar gas in the processing period P4 is less than the flow rate of the Ar gas in the processing period P3.

In the processing period P1, a shape of a mask on the substrate W may be adjusted by chemical species supplied from the plasma of the processing gas. In the processing period P2, a carbon-containing deposit may be formed on the surface of the substrate W by the chemical species supplied from the plasma of the processing gas. In the processing period P3, a region of a film of the substrate W exposed through an opening of the mask may be etched by the chemical species supplied from the plasma of the processing gas. The film may be a silicon-containing film such as a silicon oxide film. In the processing period P4, the film may be over-etched by the chemical species supplied from the plasma of the processing gas.

In one embodiment, when the electric bias EB is the voltage pulse sequence, each of the plurality of processing conditions may further include at least one of the power level of the source radio-frequency power HF or pulse HFP, the level of the electric bias EB or pulse EBP, the duty ratio (ON duty ratio) of the voltage pulse PV, the bias frequency, or the internal pressure of the plasma processing chamber 10. Alternatively, when the electric bias EB is the bias radio-frequency power LF, each of the plurality of processing conditions may further include at least one of the power level of the source radio-frequency power HF or pulse HFP, the level of the electric bias EB or pulse EBP, the bias frequency, or the internal pressure of the plasma processing chamber 10.

In one example, as shown in FIG. 6, the power level of the pulse HFP in the processing period P4 is lower than the power level of the pulse HFP in each of the processing periods P1 to P3. The level of the pulse EBP in the processing period P3 is higher than the level of the pulse EBP in each of the processing periods P1 and P2, and the level of the pulse EBP in the processing period P4 is higher than the level of the pulse EBP in the processing period P3. The duty ratio of the voltage pulse PV in the processing period P2 and the duty ratio of the voltage pulse PV in the processing period P3 are higher than the duty ratio of the voltage pulse PV in the processing period P1 and the duty ratio of the voltage pulse PV in the processing period P4. The internal pressure of the plasma processing chamber 10 in the processing period P4 is higher than the internal pressure of the plasma processing chamber 10 in each of the processing periods PI to P3.

The radio-frequency power supply 31 uses a unique frequency set in each of the plurality of processing periods (e.g., the processing periods P1 to P4) in order to reduce the reflection of the source radio-frequency power HF from a load. For example, the radio-frequency power supply 31 uses a first frequency set in the first processing period and a second frequency set in the second processing period. The unique frequency set is determined so as to reduce the degree of reflection of the source radio-frequency power HF from the load under the corresponding processing conditions. The unique frequency set includes a plurality of frequencies. The radio-frequency power supply 31 uses a plurality of frequencies included in the unique frequency set in each of the plurality of processing periods as source frequencies for each of the plurality of phase periods SP of the waveform period CY.

In the plasma processing apparatus 1, a frequency set determined to reduce the degree of reflection of the source radio-frequency power HF from the load in the plurality of phase periods SP in the waveform period CY is selected according to at least the processing gas. Therefore, it is possible to reduce the degree of reflection of the source radio-frequency power HF in the plurality of phase periods in the waveform period CY in each of two or more processing periods in which different processing gases are used.

In one embodiment, in each of the plurality of processing periods (e.g., the processing periods P1 to P4), as shown in FIG. 6, the pulse HFP is supplied prior to the pulse EBP. In the period in which the pulse HFP precedes the pulse EBP, plasma is ignited. In the period in which the pulse HFP precedes the pulse EBP in each of the plurality of processing periods, the radio-frequency power supply 31 uses a predetermined source frequency for plasma ignition. The source frequency for plasma ignition may be designated to the radio-frequency power supply 31 by the controller 2.

In one embodiment, a unique frequency set for each of a plurality of processing periods (e.g., the processing periods P1 to P4) may be registered in a corresponding frequency table in the memory of the plasma processing apparatus 1. For example, a first frequency set and a second frequency set may be respectively registered in a first frequency table and a second frequency table of a memory. This memory may be the memory 2a2 or the memory in the radio-frequency power supply 31.

In one embodiment, the bias power supply 32 may supply the pulse EBP in each of a plurality of processing periods (e.g., the processing periods P1 to P4). The bias power supply 32 may repeatedly supply the pulse EBP in each of a plurality of pulse period sequences. Each of the plurality of pulse period sequences includes a plurality of pulse periods. The plurality of pulse periods is a repetition of the corresponding processing period among the plurality of processing periods (e.g., the processing periods P1 to P4). The bias power supply 32 supplies the pulse EBP in each of the plurality of pulse periods included in each of the plurality of pulse period sequences. In one example, as shown in FIG. 6, the bias power supply 32 repeatedly supplies the pulse EBP in each of four pulse period sequences, which are repetitions of the processing periods P1 to P4, respectively. The four pulse period sequences are composed of repetitions of the corresponding processing period (i.e., the pulse period) among the processing periods P1 to P4.

The radio-frequency power supply 31 may supply the pulse HFP in each of a plurality of processing periods (e.g., the processing periods P1 to P4). The radio-frequency power supply 31 may repeatedly supply the pulse HFP in each of the plurality of pulse period sequences mentioned above. In one example, as shown in FIG. 6, the radio-frequency power supply 31 repeatedly supplies the pulse HFP in each of four pulse period sequences which are repetitions of the processing periods P1 to P4. As shown in FIG. 6, in at least a portion of each pulse period, the pulse HFP is supplied simultaneously with the pulse EBP.

In one embodiment, the radio-frequency power supply 31 may use a unique frequency set registered in the corresponding frequency table in one or more waveform periods CY in each processing period or each pulse period. Then, the radio-frequency power supply 31 may adjust the source frequency for each of the plurality of phase periods SP of the waveform period CY in each processing period or each pulse period by a first feedback. In each processing period or each pulse period, the first feedback adjusts the source frequency for each phase period SP according to the degree of reflection of the source radio-frequency power HF obtained by using different source frequencies in the same phase period in two or more preceding waveform periods. Details of the first feedback will be described later.

In one embodiment, the radio-frequency power supply 31 may adjust the source frequency for the phase period SP in each pulse period by a second feedback. In each pulse period sequence, the second feedback adjusts the source frequency for the phase period SP in each pulse period according to the degree of reflection of the source radio-frequency power HF obtained by using different source frequencies in the same phase period in the same waveform period in two or more preceding pulse periods. The radio-frequency power supply 31 may use both the first feedback and the second feedback. Details of the second feedback will be described later.

In one embodiment, the radio-frequency power supply 31 may supply a source radio-frequency power HF having a power level lower than that of the pulse HFP to the radio-frequency electrode in an OFF period P_{OFF} in at least one pulse period (e.g., the processing period P3 in FIG. 6). The source frequency of the source radio-frequency power HF in the OFF period P_{OFF} is determined so as to reduce the degree of reflection of the source radio-frequency power HF. The source frequency may be a constant frequency or may vary with time.

Now, the first feedback and the second feedback will be described.

### First Feedback

The first feedback is performed to adjust the source frequency for the plurality of phase periods SP in each of the plurality of waveform periods CY in each processing period or each pulse period. Each of the plurality of waveform periods CY includes N phase periods SP(1) to SP(N), where N is an integer equal to or greater than 2. The N phase periods SP(1) to SP(N) divide each of the plurality of waveform periods CY into N phase periods. In the following description, a waveform period CY(m) represents an m^{th} waveform period among a plurality of consecutive waveform periods CY. A phase period SP(n) represents an n^{th} phase period among the phase periods SP(1) to SP(N). Further, a phase period SP(m, n) represents the n^{th} phase period in the waveform period CY(m).

The adjustment of the source frequency in the first feedback may be performed by the radio-frequency power supply 31 (or its signal generator 31g). The radio-frequency power supply 31 adjusts the source frequency of the source radio-frequency power HF in the phase period SP(m, n) in response to a change in the degree of reflection of the source radio-frequency power HF.

In order to determine the degree of reflection of the source radio-frequency power HF, the plasma processing apparatus 1 may further include a sensor 35 and/or a sensor 36. The sensor 35 is configured to measure a power level Pr of a reflected wave of the source radio-frequency power HF from the load. The sensor 35 includes, for example, a directional coupler. The directional coupler may be provided between the radio-frequency power supply 31 and the matching device 33. The sensor 35 may be configured to further measure a power level Pf of a traveling wave of the source radio-frequency power HF. The power level Pr of the reflected wave measured by the sensor 35 is notified to the radio-frequency power supply 31. In addition, the power level Pf of the traveling wave may be notified from the sensor 35 to the radio-frequency power supply 31.

The sensor 36 includes a voltage sensor and a current sensor. The sensor 36 is configured to measure a voltage VHF and a current IHF in a power supply path that connects the radio-frequency power supply 31 and the radio-frequency electrode to each other. The source radio-frequency power HF is supplied to the radio-frequency electrode via the power supply path. The sensor 36 may be provided between the radio-frequency power supply 31 and the matching device 33. The voltage VHF and the current IHF are notified to the radio-frequency power supply 31.

The radio-frequency power supply 31 generates a representative value from the measured values in each of the plurality of phase periods SP. The measured value may be the power level Pr of the reflected wave acquired by the sensor 35. The measured value may be a value of a ratio of the power level Pr of the reflected wave to an output power level of the source radio-frequency power HF (i.e., the reflectance). The measured value may be a phase difference θ between the voltage VHF and the current IHF acquired by the sensor 36 in each of the plurality of phase periods SP. The measured value may be an impedance Z on the load side of the radio-frequency power supply 31 in each of the plurality of phase periods SP. The impedance Z is determined from the voltage VHF and the current IHF acquired by the sensor 36. The representative value may be an average value or a maximum value of the measured values in each of the plurality of phase periods SP. The radio-frequency power supply 31 uses the representative value in each of the plurality of phase periods SP as a value representing the degree of reflection of the source radio-frequency power HF.

In the first feedback, the radio-frequency power supply 31 specifies a change in the degree of reflection by using different source frequencies in the corresponding phase periods SP(n) in each of two or more waveform periods CY prior to the waveform period CY(m) within each processing period or each pulse period.

By using the different source frequencies in the phase periods SP(n) in each of two or more waveform periods CY, it is possible to specify a relationship between the change in source frequency (frequency shift) and the change in the degree of reflection of the source radio-frequency power. Therefore, according to the plasma processing apparatus 1, it is possible to adjust the source frequency used in the phase period SP(m, n) in response to the change in the degree of reflection so as to reduce the degree of reflection. Further, according to the plasma processing apparatus 1, it is possible to quickly reduce the degree of reflection in each of the waveform periods CY in which the electric bias EB is applied to the bias electrode of the substrate support 11.

In one embodiment, the two or more waveform periods CY prior to the waveform period CY(m) include a waveform period CY(m-M₁) and a waveform period CY(m-M₂), where M₁ and M₂ are natural numbers that satisfy M₁>M₂. In one embodiment, the waveform period CY(m-M₁) is a waveform period CY(m-2Q), and the waveform period CY(m-M₂) is a waveform period CY(m-Q). “Q” and “M₂” may be “1”, and “2Q” and “M₁” may be “2”. “Q” may be an integer equal to or greater than 2.

In the first feedback, the radio-frequency power supply 31 gives, to a source frequency f (m-M₂, n), an one-direction frequency shift from the source frequency f(m-M₁, n), where f(m, n) represents the source frequency of the source radio-frequency power HF used in the phase period SP(m, n). f(m, n) is expressed as f(m, n)=f(m-M₂, n)+Δ(m, n). Δ(m, n) represents an amount of the frequency shift. The one-direction frequency shift is one of a frequency decrease and a frequency increase. When the one-direction frequency shift is a frequency decrease, Δ(m, n) has a negative value. When the one-direction frequency shift is a frequency increase, Δ(m, n) has a positive value.

In the first feedback, when the degree of reflection is reduced by using the source frequency f(m-M₂, n) obtained by the one-direction frequency shift, the radio-frequency power supply 31 sets the source frequency f(m, n) to a frequency having the one-direction frequency shift with respect to the source frequency f(m-M₂, n). For example, when the power level Pr(m-M₂, n) is reduced from the power level Pr(m-M₁, n) by the one-direction frequency shift, the radio-frequency power supply 31 sets the source frequency f(m, n) to a frequency having the one-direction frequency shift with respect to the source frequency f(m-M₂, n). Pr(m, n) represents the power level Pr of the reflected wave of the source radio-frequency power HF in the phase period SP(m, n).

In the first feedback, the degree of reflection may be increased by using the source frequency f(m-M₂, n) obtained by the one-direction frequency shift. For example, the power level Pr(m-M₂, n) of the reflected wave may be increased from the power level Pr(m-M₁, n) of the reflected wave by the one-direction frequency shift. In this case, the radio-frequency power supply 31 may set the source frequency f(m, n) to a frequency having an other-direction frequency shift with respect to the source frequency f(m-M₂, n).

In another embodiment, the source frequency of the source radio-frequency power HF in the phase period SP(m, n) may be determined as a frequency that minimizes the degree of reflection from two or more degrees of reflection (e.g., power levels Pr) obtained by using different source frequencies in the corresponding phase periods SP(n) in two or more waveform periods CY prior to the waveform period CY(m). The frequency that minimizes the degree of reflection may be determined by a least square method using each of the different source frequencies and the corresponding degrees of reflection.

### Second Feedback

Now, the second feedback will be described. In the following description, the pulse period P_{P}(k) represents a k^{th} pulse period among a plurality of pulse periods P_{P} in each pulse period sequence. Further, the waveform period CY(m) represents an m^{th} waveform period among a plurality of waveform periods CY(1) to CY(M) in each of the plurality of pulse periods P_{P} in each pulse period sequence. Further, the waveform period CY(k, m) represents the m^{th} waveform period in the pulse period P_{P}(k) in each pulse period sequence. Further, the phase period SP(n) represents an n^{th} phase period among the plurality of phase periods SP(1) to SP(N) in each of the plurality of waveform periods CY in each of the plurality of pulse periods P_{P} in each pulse period sequence. Further, the phase period SP(m, n) represents the n^{th} phase period in the waveform period CY m). Further, the phase period SP(k, m, n) represents the n^{th} phase period in the waveform period CY(m) in the pulse period P_{P}(k) in each pulse period sequence.

In the second feedback, the radio-frequency power supply 31 adjusts the source frequency f(k, m, n) in response to the change in the degree of reflection of the source radio-frequency power HF. In the second feedback, the degree of reflection is determined in the same manner as the degree of reflection in the first feedback. In the second feedback, the change in the degree of reflection is determined by using the different source frequencies of the source radio-frequency power HF in the corresponding phase periods SP(n) in the waveform period CY(m) in two or more pulse periods P_{P} in each pulse period sequence. In each pulse period sequence, each of the two or more pulse periods P_{P} is a pulse period preceding the pulse period P_{P}(k).

In the second feedback, by using the different source frequencies in the same phase period in the same waveform period in each of two or more pulse periods P_{P}, it is possible to specify a relationship between the change in source frequency (frequency shift) and the change in the degree of reflection of the source radio-frequency power. Therefore, according to the second feedback, it is possible to adjust the source frequency used in the phase period SP(k, m, n) in response to the change in the degree of reflection so as to reduce the degree of reflection. Further, according to the second feedback, it is possible to quickly reduce the degree of reflection in each of the plurality of waveform periods CY in each of the plurality of pulse periods Pp in each pulse period sequence.

In each pulse period sequence, the two or more pulse periods Pp preceding the pulse period P_{P}(k) include a (k-K₁)^{th} pulse period P_{P}(k-K₁) and a (k-K₂)^{th} pulse period P_{P}(k-K₂), where K₁ and K₂ are natural numbers that satisfy K₁>K₂.

In one embodiment, the pulse period P_{P}(k-K₁) is a pulse period P_{P}(k-₂). The pulse period P_{P}(k-K₂) is a pulse period after the pulse period P_{P}(k-K₁), and is a pulse period P_{P}(k-1) in one embodiment. That is, in one embodiment, K₂ and K₁ are 1 and 2, respectively.

The radio-frequency power supply 31 gives, to the source frequency f(k-K₂, m, n) in the phase period SP(k-K₂, m, n), an one-direction frequency shift from the source frequency in the phase period SP(k-K₁, m, n). Here, f(k, m, n) represents the source frequency of the source radio-frequency power HF used in the phase period SP(k, m, n). f(k, m, n) is expressed as f(k, m, n)=f(k-K2, m, n)+Δ(k, m, n). Δ(k, m, n) represents an amount of the frequency shift. The one-direction frequency shift is one of a frequency decrease and a frequency increase. When the one-direction frequency shift is a frequency decrease, Δ(k, m, n) has a negative value. When the one-direction frequency shift is a frequency increase, Δ(k, m, n) has a positive value.

In the second feedback, when the degree of reflection is reduced by using the source frequency f(k-K₂, m, n) obtained by the one-direction frequency shift, the radio-frequency power supply 31 sets the source frequency f(k, m, n) to a frequency having the one-direction frequency shift with respect to the source frequency f(k-K₂, m, n). For example, when the power level Pr(k-K₂, m, n) is reduced from the power level Pr(k-K₁, m, n) by the one-direction frequency shift, the radio-frequency power supply 31 sets the source frequency f(k, m, n) to a frequency having the one-direction frequency shift with respect to the source frequency f(k-K₂, m, n). Pr(k, m, n) represents the power level Pr of the reflected wave of the source radio-frequency power HF in the phase period SP(k, m, n).

In the second feedback, the degree of reflection may be increased by using the source frequency f(k-K₂, m, n) obtained by a one-direction frequency shift. For example, the power level Pr(k-K₂, m, n) of the reflected wave may be increased from the power level Pr(k-K₁, m, n) of the reflected wave by the one-direction frequency shift. In this case, the radio-frequency power supply 31 may set the source frequency f(k, m, n) to a frequency having an other-direction frequency shift with respect to the source frequency f(k-K₂, m, n).

Alternatively, in each pulse period sequence, the source frequency f(k, m, n) may be determined as a frequency that minimizes the degree of reflection from two or more degrees of reflection (e.g., power levels Pr) obtained by using the different source frequencies of the source radio-frequency power HF in the corresponding phase periods SP(n) in the waveform period CY(m) in two or more pulse periods P_{P} preceding the pulse period P_{P}(k). The frequency that minimizes the degree of reflection may be determined by a least square method using each of the different source frequencies and the corresponding degrees of reflection.

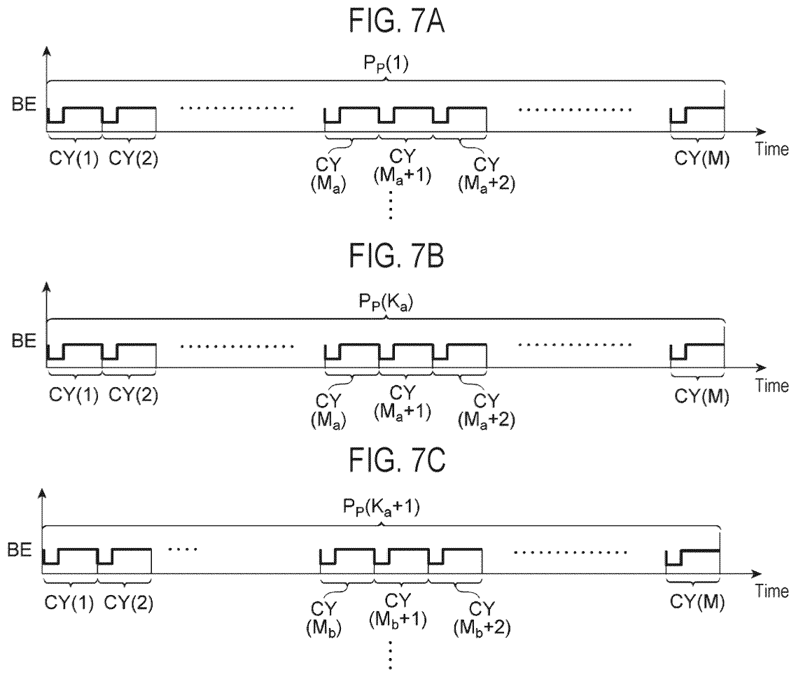

Hereinafter, FIGS. 7A to 7C will be referred to. Each of FIGS. 7A to 7C is a view showing a pulse period within a pulse period sequence relating to the plasma processing apparatus according to one exemplary embodiment.

The plurality of pulse periods P_{P} in each pulse period sequence may include the first to Kₐ^{th} pulse periods P_{P}(1) to P_{P}(Kₐ), where Kₐ is a natural number equal to or greater than 2. The radio-frequency power supply 31 may use a frequency set registered in the corresponding frequency table in each of the first to Mₐ^{th} waveform periods CY(1) to CY(Mₐ) among the plurality of waveform periods CY included in each of the pulse periods P_{P}(1) to P_{P}(Kₐ). The radio-frequency power supply 31 uses, as source frequencies, a plurality of frequencies included in the frequency set registered in the corresponding frequency table in the plurality of phase periods SP in each of the first to Mₐ^{th} waveform periods CY(1) to CY(Mₐ) in each of the pulse periods P_{P}(1) to P_{P}(Kₐ).

The radio-frequency power supply 31 may perform the above-mentioned first feedback after the waveform period CY(Mₐ) among the plurality of waveform periods CY in each of the pulse periods P_{P}(1) to P_{P}(Kₐ) in each pulse period sequence. That is, the radio-frequency power supply 31 may perform the above-mentioned first feedback in the waveform periods CY(Mₐ+1) to CY(M) included in each of the pulse periods P_{P}(1) to P_{P}(Kₐ) in each pulse period sequence.

In one embodiment, the plurality of pulse periods P_{P} in each pulse period sequence may further include (Kₐ+1)^{th} to K_{b}^{th} pulse periods P_{P}(Kₐ+1) to P_{P}(K), where K is a natural number representing the order of the final pulse period P_{P} in each pulse period sequence.

The radio-frequency power supply 31 may perform the above-mentioned second feedback in the first to M_{b}^{th} waveform periods CY(1) to CY(M_{b}) included in each of the pulse periods P_{P}(Kₐ+1) to P_{P}(K) in each pulse period sequence, where M_{b} is a natural number. The radio-frequency power supply 31 may also perform the above-mentioned first feedback after the waveform period CY(M_{b}) in each of the pulse periods P_{P}(Kₐ+1) to P_{P}(K) in each pulse period sequence. That is, the radio-frequency power supply 31 may perform the above-mentioned first feedback in the waveform periods CY(M_{b}+1) to CY(M) included in each of the pulse periods P_{P}(Kₐ+1) to P_{P}(K) in each pulse period sequence.

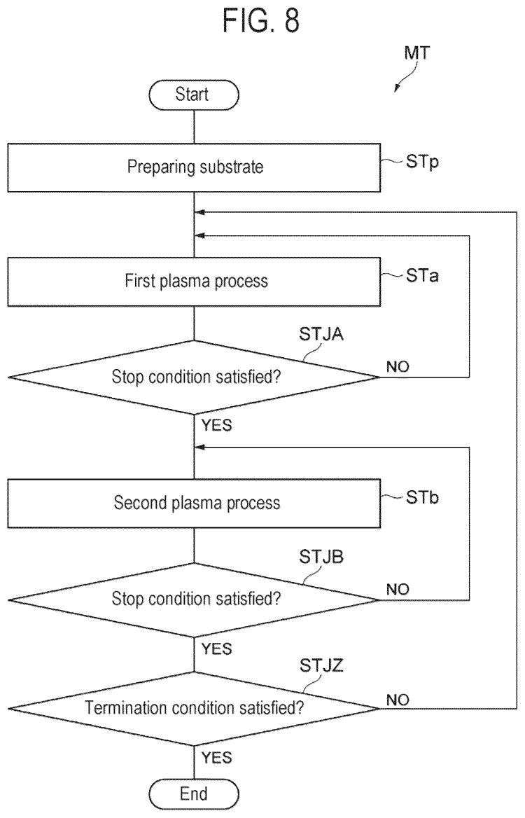

Hereinafter, FIG. 8 will be referred to. FIG. 8 is a flowchart for explaining a plasma processing method according to one exemplary embodiment. The plasma processing method shown in FIG. 8 (hereinafter referred to as “method MT”) may be performed using the plasma processing apparatus 1.

As shown in FIG. 8, the method MT starts with Operation STp. In Operation STp, the substrate W is prepared on the substrate support 11 inside the plasma processing chamber 10.

In the method MT, as described above with respect to the plasma processing apparatus 1, a plurality of processing conditions different from one another are used as processing conditions for plasma processing on the substrate W in a plurality of processing periods, respectively.

In one embodiment, Operation STa is performed in a first processing period. In Operation STa, a first plasma process is performed under a first processing condition. The first processing condition includes supplying a first processing gas from which plasma is generated into the plasma processing chamber 10. Operation STa may be performed once. Alternatively, Operation STa may be repeated. That is, the pulse EBP may be repeatedly supplied in a first pulse period sequence composed of repetitions of the first processing period. When Operation STa is repeated, it is determined in Operation STJA whether or not a stop condition is satisfied. In Operation STJA, the stop condition is satisfied when the number of repetitions of Operation STa reaches a predetermined number. When it is determined in Operation STJA that the stop condition is not satisfied, Operation STa is performed again. When it is determined in Operation STJA that the stop condition is satisfied, the repetition of Operation STa is terminated.

In one embodiment, Operation STb is performed in a second processing period. In Operation STb, a second plasma process is performed under a second processing condition. The second processing condition includes supplying a second processing gas from which plasma is generated into the plasma processing chamber 10. The second processing gas is a processing gas different from the first processing gas. Operation STb may be performed once. Alternatively, Operation STb may be repeated. That is, the pulse EBP may be repeatedly supplied in a second pulse period sequence composed of repetitions of the second processing period. When Operation STb is repeated, it is determined in Operation STJB whether a stop condition is satisfied. In Operation STJB, the stop condition is satisfied when the number of repetitions of Operation STb reaches a predetermined number. When it is determined in Operation STJB that the stop condition is not satisfied, Operation STb is performed again. When it is determined in Operation STJB that the stop condition is satisfied, the repetition of Operation STb is terminated.

In the method MT, a cycle including Operations STa and STb may be repeated. In this case, it is determined in Operation STJZ whether or not a termination condition is satisfied. In Operation STJZ, the termination condition is satisfied when the number of repetitions of the cycle reaches a predetermined number. When it is determined in Operation STJZ that the termination condition is not satisfied, the cycle is performed again. When it is determined in Operation STJZ that the stop condition is satisfied, the repetition of the cycle is terminated.

The method MT may include three or more operations of performing the plasma processing on the substrate W. The three or more operations include Operation STa and Operation STb. The three or more operations are performed in three or more processing periods, respectively. In the three or more processing periods, as described above, three or more processing conditions different from one another are used as processing conditions for the plasma processing on the substrate W, respectively. The cycle of the method MT may include the above-described three or more operations.

In the method MT, in the first processing period, a plurality of frequencies included in a first frequency set are used as source frequencies for each of a plurality of phase periods SP in a waveform period CY of the electric bias EB. The first frequency set is determined so as to reduce the degree of reflection of the source radio-frequency power HF from the load in the first processing period. In addition, in the second processing period, a plurality of frequencies included in a second frequency set different from the first frequency set are used as source frequencies for each of the plurality of phase periods SP in the waveform period CY of the electric bias EB. The second frequency set is determined so as to reduce the degree of reflection of the source radio-frequency power HF from the load in the second processing period. As described above, in the method MT, a plurality of different frequency sets are used in the above-mentioned plurality of processing periods.

Although various exemplary embodiments have been described above, the present disclosure is not limited to the above-described exemplary embodiments, and various additions, omissions, substitutions, and modifications may be made. In addition, elements in different embodiments may be combined to form other embodiments.

In other embodiments, the plasma processing apparatus may be an inductively coupled plasma processing apparatus, an ECR plasma processing apparatus, a helicon wave excited plasma processing apparatus, or a surface wave plasma processing apparatus. In any of the plasma processing apparatuses, source radio-frequency power HF is used to generate plasma, and the source frequency of the source radio-frequency power HF is adjusted as described above with respect to the plasma processing apparatus 1.

Various exemplary embodiments included in the present disclosure are now described in [E1] to [E9] below.

### [E1]

A plasma processing apparatus includes a chamber; a substrate support arranged inside the chamber, a gas supplier configured to supply a gas into the chamber, a radio-frequency power supply configured to a supply source radio-frequency power to generate plasma from the gas inside the chamber, and a bias power supply electrically coupled to the substrate support and configured to generate electric bias, wherein during a first processing period in which a first processing condition including supplying a first processing gas from the gas supplier into the chamber is applied, the radio-frequency power supply uses a plurality of frequencies, which are included in a first frequency set determined to reduce a degree of reflection of the source radio-frequency power from a load, as source frequencies of the source radio-frequency power for each of a plurality of phase periods in a waveform period of the electric bias, and during a second processing period in which a second processing condition including supplying a second processing gas from the gas supplier into the chamber is applied, the radio-frequency power supply uses a plurality of frequencies, which are included in a second frequency set different from the first frequency set and determined to reduce the degree of reflection of the source radio-frequency power from the load, as the source frequencies for each of the plurality of phase periods in the waveform period of the electric bias.

In the embodiment of [E1] above, the frequency set determined to reduce the degree of reflection of the source radio-frequency power from the load during the plurality of phase periods in the waveform period of the electric bias is selected according to at least the processing gas. Thus, it is possible to reduce the degree of reflection of the source radio-frequency power during the plurality of phase periods in the waveform period of the electric bias in each of two or more periods in which different processing gases are used.

### [E2]

In the plasma processing apparatus of [E1] above, the electric bias is a voltage pulse sequence including voltage pulses generated periodically at a time interval equal to a time length of the waveform period, and each of the first processing condition and the second processing condition further includes at least one of a power level of the source radio-frequency power, a level of the electric bias, a duty ratio of the voltage pulse of the electric bias in the waveform period, a bias frequency as a reciprocal of the waveform period, or an internal pressure of the chamber.

### [E3]

In the plasma processing apparatus of [E1] above, the electric bias is a bias radio-frequency power having the waveform period, and each of the first process condition and the second process condition further includes at least one of a power level of the source radio-frequency power, a level of the electric bias, a bias frequency as a reciprocal of the waveform period, or an internal pressure of the chamber.

### [E4]

In the plasma processing apparatus of any one of [E1] to [E3] above, the plurality of frequencies of the first frequency set are registered in a first frequency table prepared in advance in a memory of the plasma processing apparatus, and the plurality of frequencies of the second frequency set are registered in a second frequency table prepared in advance in the memory.

### [E5]

In the plasma processing apparatus of any one of [E1] to [E4] above, the radio-frequency power supply is configured to, during each of the first processing period and the second processing period, adjust the source frequency for an n^{th} phase period in an m^{th} waveform period of the electric bias in response to a change in a degree of reflection of the source radio-frequency power when a different frequency is used as the source frequency for the n^{th} phase period in two or more waveform periods of the electric bias, which precede the m^{th} waveform period.

### [E6]

In the plasma processing apparatus of any one of [E1] to [E5] above, the bias power supply is configured to supply a pulse of the electric bias during each of a plurality of pulse periods which are repetitions of the first processing period included in a first pulse period sequence, and supply a pulse of the electric bias during each of a plurality of pulse periods which are repetitions of the second processing period included in a second pulse period sequence.

### [E7]

In the plasma processing apparatus of [E6] above, the radio-frequency power supply is configured to, during each of the first processing period and the second processing period, adjust the source frequency for an n^{th} phase period in an m^{th} waveform period in a k^{th} pulse period in response to a change in a degree of reflection of the source radio-frequency power when a different frequency is used as the source frequency for the n^{th} phase period in the m^{th} waveform period in two or more pulse periods preceding the k^{th} pulse period.

### [E8]

In the plasma processing apparatus of [E6] or [E7] above, the radio-frequency power supply is configured to supply a pulse of the source radio-frequency power in each of the plurality of pulse periods included in the first pulse period sequence, and supply a pulse of the source radio-frequency power in each of the plurality of pulse periods included in the second pulse period sequence.

### [E9]

A plasma processing method includes a substrate on a substrate support inside a chamber of a plasma processing apparatus, performing a first plasma process on the substrate using a first processing condition including supplying a first processing gas from a gas supplier into the chamber during a first processing period, and performing a second plasma process on the substrate using a second processing condition including supplying a second processing gas from the gas supplier into the chamber during a second processing period. During each of the first processing period and the second processing period, source radio-frequency power for plasma generation is supplied, and electric bias is supplied from a bias power supply to the substrate support, and during the first processing period, a plurality of frequencies included in a first frequency set determined to reduce a degree of reflection of the source radio-frequency power from a load are used as the source frequency of the source radio-frequency power for each of a plurality of phase periods in a waveform period of the electric bias, and during the second processing period, a plurality of frequencies included in a second frequency set different from the first frequency set and determined to reduce a degree of reflection of the source radio-frequency power from the load are used as the source frequency for each of the plurality of phase periods in the waveform period of the electric bias.

According to the present disclosure in some embodiments, it is possible to reduce a degree of reflection of source radio-frequency power.

From the foregoing description, it should be understood that various embodiments of the present disclosure have been described herein for purposes of illustration, and that various modifications may be made without departing from the scope and spirit of the present disclosure. Accordingly, the various embodiments disclosed herein are not intended to be limiting, and the true scope and spirit of the present disclosure are indicated by the appended claims.

What is claimed is:

1. A plasma processing apparatus, comprising:
a chamber;
a substrate support arranged inside the chamber;
a gas supplier configured to supply a gas into the chamber;
a radio-frequency power supply configured to supply a source radio-frequency power to generate plasma from the gas inside the chamber; and
a bias power supply electrically coupled to the substrate support and configured to generate electric bias,
wherein during a first processing period in which a first processing condition including supplying a first processing gas from the gas supplier into the chamber is applied, the radio-frequency power supply uses a plurality of frequencies, which are included in a first frequency set determined to reduce a degree of reflection of the source radio-frequency power from a load, as source frequencies of the source radio-frequency power for each of a plurality of phase periods in a waveform period of the electric bias, and
during a second processing period in which a second processing condition including supplying a second processing gas from the gas supplier into the chamber is applied, the radio-frequency power supply uses a plurality of frequencies, which are included in a second frequency set different from the first frequency set and determined to reduce the degree of reflection of the source radio-frequency power from the load, as the source frequencies for each of the plurality of phase periods in the waveform period of the electric bias.

2. The plasma processing apparatus of claim 1, wherein the electric bias is a voltage pulse sequence including voltage pulses generated periodically at a time interval equal to a time length of the waveform period, and
wherein each of the first processing condition and the second processing condition further includes at least one of a power level of the source radio-frequency power, a level of the electric bias, a duty ratio of the voltage pulse of the electric bias in the waveform period, a bias frequency as a reciprocal of the waveform period, or an internal pressure of the chamber.

3. The plasma processing apparatus of claim 1, wherein the electric bias is a bias radio-frequency power having the waveform period, and
wherein each of the first process condition and the second process condition further includes at least one of a power level of the source radio-frequency power, a level of the electric bias, a bias frequency as a reciprocal of the waveform period, or an internal pressure of the chamber.

4. The plasma processing apparatus of claim 1, wherein the plurality of frequencies of the first frequency set are registered in a first frequency table prepared in advance in a memory of the plasma processing apparatus, and
wherein the plurality of frequencies of the second frequency set are registered in a second frequency table prepared in advance in the memory.

5. The plasma processing apparatus of claim 1, wherein the radio-frequency power supply is configured to, during each of the first processing period and the second processing period, adjust the source frequency for an n^{th} phase period in an m^{th} waveform period of the electric bias in response to a change in a degree of reflection of the source radio-frequency power when a different frequency is used as the source frequency for the n^{th} phase period in two or more waveform periods of the electric bias, which precede the m^{th} waveform period.

6. The plasma processing apparatus of claim 1, wherein the bias power supply is configured to supply a pulse of the electric bias during each of a plurality of pulse periods which are repetitions of the first processing period included in a first pulse period sequence, and supply a pulse of the electric bias during each of a plurality of pulse periods which are repetitions of the second processing period included in a second pulse period sequence.

7. The plasma processing apparatus of claim 6, wherein the radio-frequency power supply is configured to, during each of the first processing period and the second processing period, adjust the source frequency for an n^{th} phase period in an m^{th} waveform period in a k^{th} pulse period in response to a change in a degree of reflection of the source radio-frequency power when a different frequency is used as the source frequency for the n^{th} phase period in the m^{th} waveform period in two or more pulse periods preceding the k^{th} pulse period.

8. The plasma processing apparatus of claim 6, wherein the radio-frequency power supply is configured to supply a pulse of the source radio-frequency power in each of the plurality of pulse periods included in the first pulse period sequence, and supply a pulse of the source radio-frequency power in each of the plurality of pulse periods included in the second pulse period sequence.

9. A plasma processing method, comprising:
preparing a substrate on a substrate support inside a chamber of a plasma processing apparatus;
performing a first plasma process on the substrate using a first processing condition including supplying a first processing gas from a gas supplier into the chamber during a first processing period; and
performing a second plasma process on the substrate using a second processing condition including supplying a second processing gas from the gas supplier into the chamber during a second processing period,
wherein during each of the first processing period and the second processing period, a source radio-frequency power for plasma generation is supplied, and electric bias is supplied from a bias power supply to the substrate support,
wherein during the first processing period, a plurality of frequencies included in a first frequency set determined to reduce a degree of reflection of the source radio-frequency power from a load are used as the source frequency of the source radio-frequency power for each of a plurality of phase periods in a waveform period of the electric bias, and
wherein during the second processing period, a plurality of frequencies included in a second frequency set different from the first frequency set and determined to reduce a degree of reflection of the source radio-frequency power from the load are used as the source frequency for each of the plurality of phase periods in the waveform period of the electric bias.
